(19) United States
(12) Patent Application Publication
(10) Pub. No.: US 2026/0305383 A1
(43) Pub. Date: Oct. 1, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Ryoya SHIRAHAMA, Tokyo (JP); Seiichiro INOKUCHI, Tokyo (JP); Shoji SAITO, Tokyo (JP)

(73) Assignee: Mitsubishi Electric Corporation, Tokyo (JP)

(21) Appl. No.: 18/879,142

(22) PCT Filed: Sep. 14, 2022
(86) PCT No.: PCT/JP2022/034364

§ 371 Date: Dec. 26, 2024

(51) Int. Cl. H10W 70/40; H10W 90/00

(52) U.S. Cl. CPC H10W 70/461; H10W 70/411; H10W 70/421; H10W 90/811

(57) ABSTRACT

The present disclosure relates to a semiconductor device, including a first heat spreader on which a first semiconductor element is mounted, a first electrode plate connected to the first heat spreader at a bent portion having an inclination, a second heat spreader on which a second semiconductor element is mounted, and a second electrode plate provided with a level difference with respect to the second heat spreader, the first electrode plate is positioned at a position higher than the first heat spreader, the second electrode plate is positioned at a position higher than the second heat spreader, the first and second electrode plates are positioned at the same height, the first and second heat spreaders are positioned at the same height, the second electrode plate is positioned above the first heat spreader, and the first electrode plate is positioned above the second heat spreader.

### TECHNICAL FIELD

The present disclosure relates to a semiconductor device, and more particularly to a semiconductor device having a direct lead bonding structure in which a semiconductor element and an electrode are directly bonded.

### BACKGROUND ART

In a power semiconductor device such as an insulated gate bipolar transistor (IGBT), a metal oxide semiconductor field effect transistor (MOSFET), and a high withstand voltage diode, a semiconductor device module is adopted in which a direct lead bonding (DLB) structure in which a semiconductor element and an electrode are directly bonded is sealed with a transfer mold resin.

For example, Patent Document 1 discloses a DLB structure in which a semiconductor element is bonded onto a die pad of a lead frame by a bonding member such as solder, and then an upper electrode of the semiconductor element and a DLB frame are bonded by the bonding member.

### PRIOR ART DOCUMENT

### Patent Document

Patent Document 1: Japanese Patent Application Laid-Open No. 2018-081947

### SUMMARY

### Problem to be Solved by the Invention

In the prior art, it is necessary to prepare a lead frame and a DLB frame and perform bonding processes with a semiconductor element respectively for them, which leads to a problem that the number of components and the number of manufacturing processes increase, and manufacturing cost increases.

The present disclosure has been made to solve the above problem, and an object of the present disclosure is to provide a semiconductor device for which the number of components and the number of manufacturing processes are reduced and the manufacturing cost is reduced.

### Means to Solve the Problem

A semiconductor device according to the present disclosure includes a first heat spreader on which a first semiconductor element is mounted, a first electrode plate connected to the first heat spreader at a bent portion having an inclination, a second heat spreader on which a second semiconductor element is mounted, and a second electrode plate provided to have a level difference with respect to the second heat spreader, in which the first electrode plate is positioned at a position higher than the first heat spreader, the second electrode plate is positioned at a position higher than the second heat spreader, the first electrode plate and the second electrode plate are positioned at a same height, the first heat spreader and the second heat spreader are positioned at a same height, the second electrode plate is positioned above the first heat spreader, the first electrode plate is positioned above the second heat spreader, the first semiconductor element is bonded to the first heat spreader and the second electrode plate, and the second semiconductor element is bonded to the second heat spreader and the first electrode plate.

### Effects of the Invention

According to the semiconductor device of the present disclosure, by preparing a frame in which the first heat spreader and the first electrode plate are provided so as to have a level difference, and a frame in which the second heat spreader and the second heat spreader are provided so as to have a level difference, it is possible to obtain the semiconductor device in which the first semiconductor element is bonded to the first heat spreader and the second electrode plate, and the second semiconductor element is bonded to the second heat spreader and the first electrode plate. It is therefore not necessary to separately provide the heat spreader and the electrode plate, which reduces the number of components. In addition, the number of manufacturing processes can be reduced by bonding the first and second semiconductor elements in a state where the two frames are superimposed.

### BRIEF DESCRIPTION OF DRAWINGS

FIG. 1 is a plan view illustrating a configuration of a semiconductor device according to a first embodiment.

FIG. 2 is a plan view illustrating a frame for manufacturing the semiconductor device of the first embodiment.

FIG. 3 is a plan view illustrating a frame for manufacturing the semiconductor device of the first embodiment.

FIG. 4 is a plan view illustrating a state in which two frames for manufacturing the semiconductor device of the first embodiment are combined.

FIG. 5 is a cross-sectional view of a frame for manufacturing the semiconductor device of the first embodiment.

FIG. 6 is a cross-sectional view of a frame for manufacturing the semiconductor device of the first embodiment.

FIG. 7 is a plan view illustrating a state in the middle of superimposing two frames for manufacturing the semiconductor device of the first embodiment.

FIG. 8 is a plan view illustrating a state in which two frames for manufacturing a semiconductor device of a second embodiment are combined.

FIG. 9 is a schematic cross-sectional view of the semiconductor device of the second embodiment.

FIG. 10 is a plan view illustrating a state in the middle of superimposing two frames for manufacturing a semiconductor device of a third embodiment.

FIG. 11 is a plan view illustrating a state in which the two frames for manufacturing the semiconductor device of the third embodiment are combined.

FIG. 12 is a plan view illustrating a frame for manufacturing a semiconductor device of a fourth embodiment.

FIG. 13 is a plan view illustrating a frame for manufacturing the semiconductor device of the fourth embodiment.

FIG. 14 is a plan view illustrating a state in which the two frames for manufacturing the semiconductor device of the fourth embodiment are combined.

FIG. 15 is a cross-sectional view of a frame for manufacturing the semiconductor device of the fourth embodiment.

FIG. 16 is a cross-sectional view of a frame for manufacturing the semiconductor device of the fourth embodiment.

FIG. 17 is a cross-sectional view of a frame for manufacturing a semiconductor device of a fifth embodiment.

FIG. 18 is a cross-sectional view of a frame for manufacturing the semiconductor device of the fifth embodiment.

FIG. 19 is a flowchart for explaining a method of manufacturing a semiconductor device of a sixth embodiment.

FIG. 20 is a plan view for explaining a manufacturing process of the semiconductor device.

FIG. 21 is a plan view for explaining the manufacturing process of the semiconductor device.

FIG. 22 is a plan view for explaining the manufacturing process of the semiconductor device.

FIG. 23 is a plan view for explaining the manufacturing process of the semiconductor device.

FIG. 24 is a plan view for explaining the manufacturing process of the semiconductor device.

FIG. 25 is a plan view illustrating a state in the middle of superimposing two frames for manufacturing a semiconductor device of a seventh embodiment.

FIG. 26 is a plan view illustrating a state in which the two frames for manufacturing the semiconductor device of the seventh embodiment are combined.

FIG. 27 is a plan view illustrating a state in the middle of superimposing two frames in a method of manufacturing a semiconductor device according to an eighth embodiment.

FIG. 28 is a plan view illustrating a state in which the two frames are combined in the method of manufacturing the semiconductor device of the eighth embodiment.

FIG. 29 is a plan view illustrating a state in the middle of superimposing two frames in a method of manufacturing a semiconductor device of a ninth embodiment.

FIG. 30 is a plan view illustrating a state in which the two frames are combined in the method of manufacturing the semiconductor device of the eighth embodiment.

FIG. 31 is a cross-sectional view for explaining a method of manufacturing a semiconductor device of a tenth embodiment.

FIG. 32 is a plan view for explaining the method of manufacturing the semiconductor device of the tenth embodiment.

### DESCRIPTION OF EMBODIMENTS

### First Embodiment

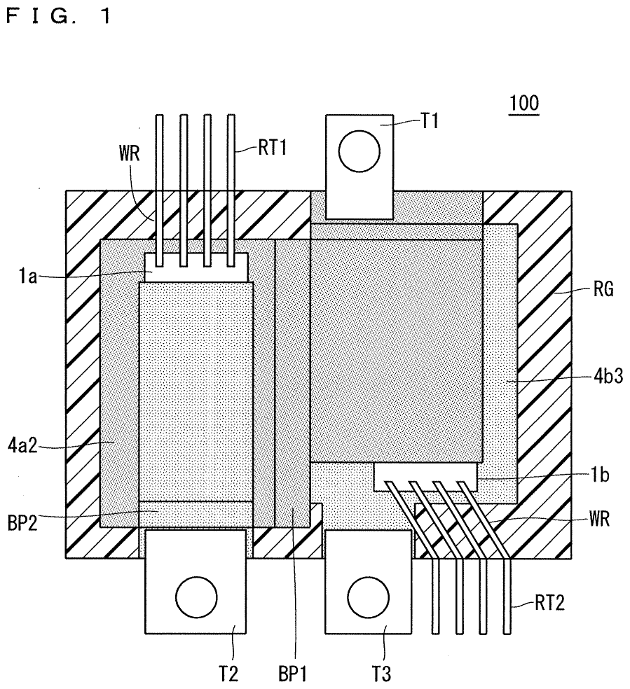

FIG. 1 is a plan view illustrating a configuration of a single-phase inverter 100 that is a semiconductor device of a first embodiment according to the present disclosure. Although the single-phase inverter 100 illustrated in FIG. 1 is resin-sealed with a molding resin, a molding resin on an upper surface is omitted, and only a molding resin RG on a lower surface is illustrated for convenience. Although only a power semiconductor element 1a (first semiconductor element) and a power semiconductor element 1b (second semiconductor element) are illustrated for convenience, if they are IGBTs or MOSFETs connected in series, they can be considered as a basic circuit of a single-phase inverter.

As illustrated in FIG. 1, in the single-phase inverter 100, a heat spreader 4a2 (first heat spreader) on which the power semiconductor element 1a such as an IGBT, a MOSFET, and a high withstand voltage diode is mounted and an electrode plate 4a1 (first electrode plate) positioned in parallel in plan view are connected to have the same electrical potential. The heat spreader 4a2 and the electrode plate 4a1 are connected at a bent portion BP1. The bent portion BP1 has an inclination such that the height is high on the electrode plate 4a1 side and is low on the heat spreader 4a2 side. Thus, there is a level difference between the heat spreader 4a2 and the electrode plate 4a1.

Further, the bent portion BP1 is provided along the entire long side of the heat spreader 4a2, and the electrode plate 4a1 and the heat spreader 4a2 are firmly engaged with each other at the bent portion BP1, so that a shape of the electrode plate 4a1 can be stabilized.

In the power semiconductor element 1a, a first main electrode provided on a lower surface side is bonded to an upper surface of the heat spreader 4a2 with a brazing material (not illustrated) such as solder, and a second main electrode provided on an upper surface side is bonded to a lower surface of an electrode plate 4b1 (second electrode plate) positioned above the heat spreader 4a2 (second heat spreader) with a brazing material (not illustrated) such as solder.

Further, a heat spreader 4b2 on which the power semiconductor element 1b is mounted is positioned below the electrode plate 4a1. In the power semiconductor element 1b, the first main electrode provided on the lower surface side is bonded to an upper surface of the heat spreader 4b2 with a brazing material (not illustrated) such as solder, and the second main electrode provided on the upper surface side is bonded to a lower surface of the electrode plate 4a1 with a brazing material (not illustrated) such as solder.

The heat spreader 4a2 and the heat spreader 4b2 are positioned in parallel in plan view, and there is no level difference between the heat spreader 4a2 and the heat spreader 4b2. On the other hand, although the electrode plate 4b1 and the heat spreader 4b2 are positioned in parallel in plan view, the electrode plate 4b1 is located at a higher position, the heat spreader 4b2 is located at a lower position, so that there is a level difference between the electrode plate 4b1 and the heat spreader 4b2.

The electrode plate 4b1 has a rectangular shape in plan view, a main terminal plate T2 is bonded to one end portion, and a main terminal plate T2 protrudes to the outside of the molding resin RG. Note that the one end portion to which the main terminal plate T2 is bonded is opposite to an end portion of the heat spreader 4a2 on which the power semiconductor element 1a is mounted. A bent portion BP2 is provided at the one end portion of the electrode plate 4b1. The bent portion BP2 has an inclination such that the height is high on the electrode plate 4b1 side and is low on the main terminal plate T2 side. As a result, there is a level difference between the electrode plate 4b1 and the heat spreader 4b2.

The heat spreader 4a2 has a rectangular shape in plan view, the power semiconductor element 1a is mounted on one end portion and is connected to a relay terminal RT1 via a wire WR, and the relay terminal RT1 protrudes to the outside of the molding resin RG.

The heat spreader 4b2 has a rectangular shape in plan view, a main terminal plate T3 is bonded to one end portion, and the main terminal plate T3 protrudes to the outside of the molding resin RG. The one end portion to which the main terminal plate T3 is bonded is on the same side as the end portion on which the power semiconductor element 1b is mounted. The power semiconductor element 1b is connected to a relay terminal RT2 via the wire WR, and the relay terminal RT2 protrudes to the outside of the molding resin RG.

The electrode plate 4a1 has a rectangular shape in plan view, a main terminal plate T1 is bonded to one end portion, and the main terminal plate T1 protrudes to the outside of the molding resin RG. The one end portion to which main terminal plate T1 is bonded is opposite to the end portion of heat spreader 4b2 on which power semiconductor element 1b is mounted.

As described above, in the single-phase inverter 100 illustrated in FIG. 1, a level difference is provided between the heat spreader 4a2 and the electrode plate 4a1, a level difference is provided between the electrode plate 4b1 and the heat spreader 4b2, the power semiconductor element 1a is positioned between the heat spreader 4a2 and the electrode plate 4b1, and the power semiconductor element 1b is positioned between the heat spreader 4b2 and the electrode plate 4a1, whereby the power semiconductor element 1a and the power semiconductor element 1b can be connected in series.

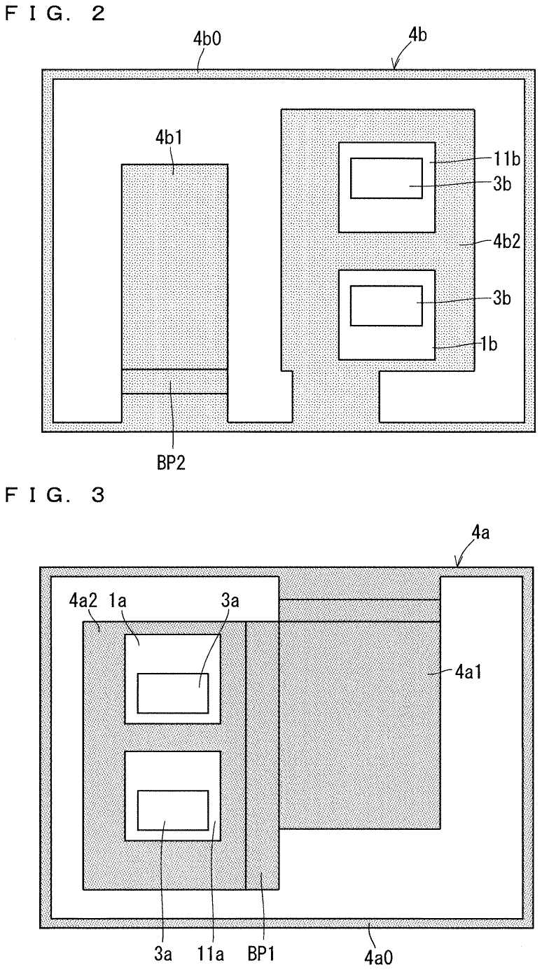

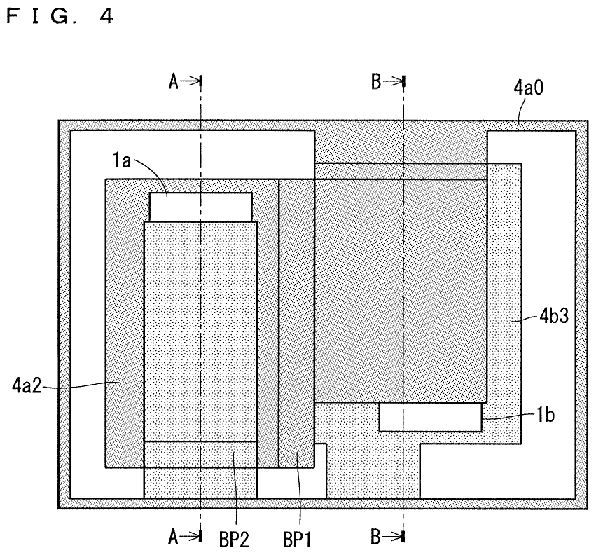

Next, a method of manufacturing a main part of the single-phase inverter 100 will be described with reference to FIGS. 2 to 6. FIGS. 2 and 3 are plan views illustrating a frame 4b and a frame 4a for manufacturing the single-phase inverter 100, respectively, and FIG. 4 is a plan view illustrating a state in which the frame 4a (first frame) and the frame 4b (second frame) are combined.

As illustrated in FIG. 2, the frame 4b includes a frame body 4b0 that defines outline of the frame 4b, the electrode plate 4b1, and the heat spreader 4b2. The frame body 4b0 is a frame having a rectangular shape in plan view and is provided such that the electrode plate 4b1 and the heat spreader 4b2 extend inward from one side of the frame body 4b0. The electrode plate 4b1 and the heat spreader 4b2 are positioned in parallel in plan view with a space therebetween, but the bent portion BP2 is provided at one end portion of the electrode plate 4b1. The bent portion BP2 has an inclination such that the height is high on one end side and is low on the frame body 4b0 side. As a result, there is a level difference between the electrode plate 4b1 and the heat spreader 4b2.

The power semiconductor element 1b and a power semiconductor element 11b are mounted on the heat spreader 4b2, and an end portion on a side on which the power semiconductor element 1b is mounted has a partially narrowed width and is integrated with the frame body 4b0.

As illustrated in FIG. 3, the frame 4a includes a frame body 4a0 that defines outline of the frame 4a, the electrode plate 4a1, and the heat spreader 4a2. The frame body 4a0 is a frame having a rectangular shape in plan view and is provided such that the electrode plate 4a1 extends inward from one side of the frame body 4a0. The electrode plate 4a1 is connected to the heat spreader 4a2 positioned in parallel in plan view at the bent portion BP1.

The bent portion BP1 has an inclination such that the height is high on the electrode plate 4a1 side and is low on the heat spreader 4a2 side. Thus, there is a level difference between the heat spreader 4a2 and the electrode plate 4a1. The power semiconductor element 1a and a power semiconductor element 11a are mounted on the heat spreader 4a2. Note that the frames 4a and 4b can be made of aluminum (Al) or copper (Cu).

As illustrated in FIGS. 2 and 3, one side of the frame body 4b0 in which the electrode plate 4b1 and the heat spreader 4b2 of the frame 4b extend and one side in which the electrode plate 4a1 of the frame 4a extends have a positional relationship of facing each other, and if the frame 4b and the frame 4a are positioned so as to be superimposed, a configuration as illustrated in FIG. 4 is obtained.

FIG. 4 illustrates a configuration of a region sealed with the molding resin RG of the single-phase inverter 100 illustrated in FIG. 1, in which the power semiconductor elements 1a and 11a are positioned between the heat spreader 4a2 and the electrode plate 4b1, and the power semiconductor elements 1b and 11b are positioned between the heat spreader 4b2 and the electrode plate 4a1.

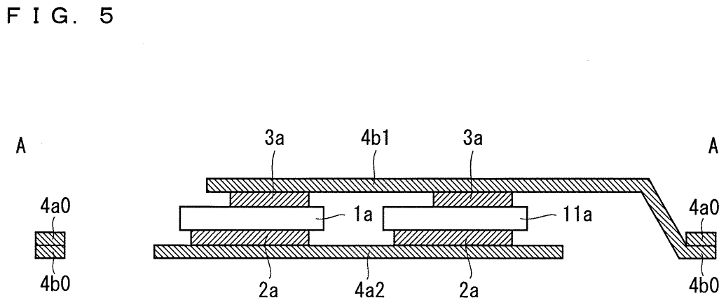

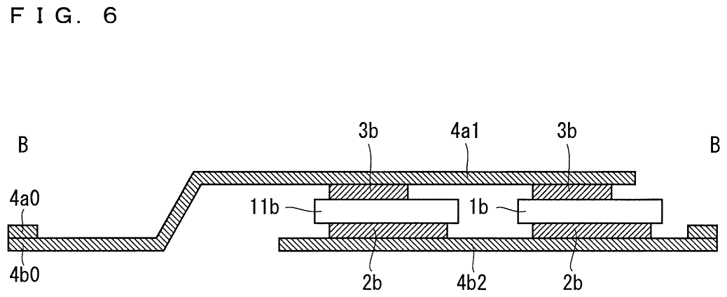

FIG. 5 is a cross-sectional view in an arrow direction taken along a line A-A in FIG. 4, and FIG. 6 is a cross-sectional view in an arrow direction taken along a line B-B in FIG. 4.

As illustrated in FIG. 5, the power semiconductor elements 1a and 11a are bonded to the heat spreader 4a2 by a brazing material 2a and are bonded to the upper electrode plate 4b1 by a brazing material (first brazing material).

In addition, as illustrated in FIG. 6, the power semiconductor elements 1b and 11b are bonded to the heat spreader 4b2 by a brazing material 2b and are bonded to the upper electrode plate 4a1 by a brazing material 3b (second brazing material). As the brazing materials 2a, 3a, 2b, and 3b, for example, solder can be used.

As described above, the electrode plate 4a1 and the heat spreader 4a2 are provided in the frame 4a, the electrode plate 4b1 and the heat spreader 4b2 are provided in the frame 4b, and the frame 4a and the frame 4b are positioned so as to be superimposed, whereby it is not necessary to separately provide the heat spreader and the electrode plate, so that the number of components is reduced. In addition, the brazing materials 3a and 3b are bonded in a state where the frame 4a and the frame 4b are superimposed, and thus, the number of manufacturing processes can be reduced.

Further, a shape of the frame can be freely designed, which increases a degree of freedom in inductance design. Still further, it is also possible to improve heat dissipation.

In addition, by configuring the outer shapes defined by the frame body 4a0 of the frame 4a and the frame body 4b0 of the frame 4b to have the same size, it is easy to align the frames at the time of superimposing the frame body 4a0 and the frame body 4b0, and alignment accuracy is also improved.

Here, as the types of the power semiconductor elements 1a and 11a, it is assumed, for example, that the power semiconductor element 1a is an IGBT, the power semiconductor element 11a is a high withstand voltage diode, and the power semiconductor element 11a is connected in antiparallel to the power semiconductor element 1a.

In addition, as the types of the power semiconductor elements 1b and 11b, it is assumed, for example, that the power semiconductor element 1b is an IGBT, the power semiconductor element 11b is a high withstand voltage diode, and the power semiconductor element 11b is connected in antiparallel to the power semiconductor element 1b.

By connecting the power semiconductor element 1b and the power semiconductor element 1a in series, the power semiconductor elements 11b and 11a can constitute an inverter that operates as a free wheeling diode.

### Second Embodiment

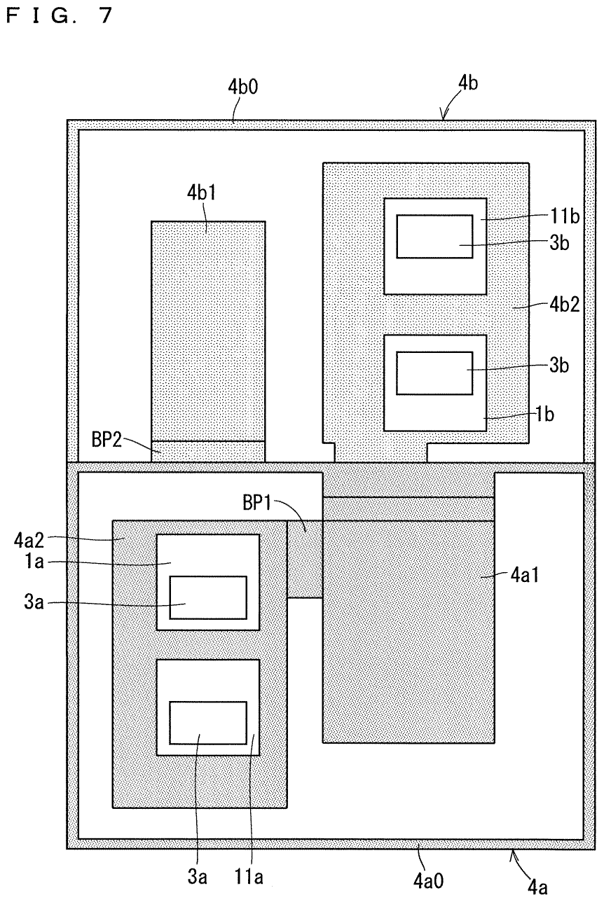

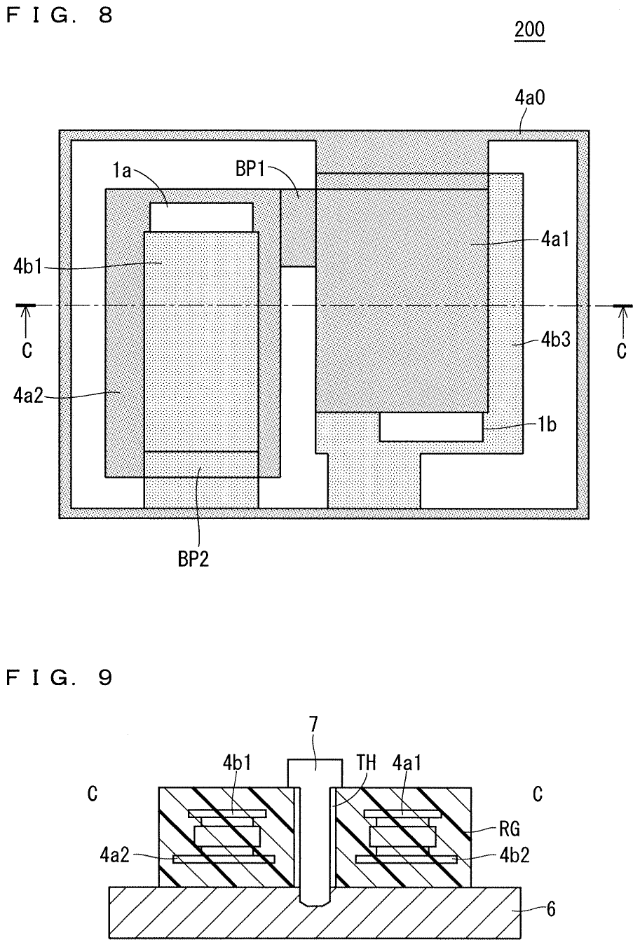

Next, a second embodiment according to the present disclosure will be described with reference to FIGS. 7 and 8. FIG. 7 is a plan view illustrating a state in the middle of superimposing the frame 4b and the frame 4a, and FIG. 8 is a plan view illustrating a state in which the frame 4a and the frame 4b are combined and illustrates a main part of a single-phase inverter 200 of the second embodiment.

In FIG. 7, the frame 4b has the same shape as that of the first embodiment illustrated in FIG. 2. However, in the frame 4a, the bent portion BP1 that bonds the electrode plate 4a1 and the heat spreader 4a2 is not provided along the entire one long side of the heat spreader 4a2, but is provided so as to connect part of the one long side and part of one long side of the electrode plate 4a1. Thus, it can be said that the bent portion BP1 is provided so as to form a slit between the electrode plate 4a1 and the heat spreader 4a2.

As illustrated in FIG. 8, as a result of a slit being formed between the electrode plate 4a1 and the heat spreader 4a2, a gap between the heat spreader 4b2 and the heat spreader 4a2 can be used.

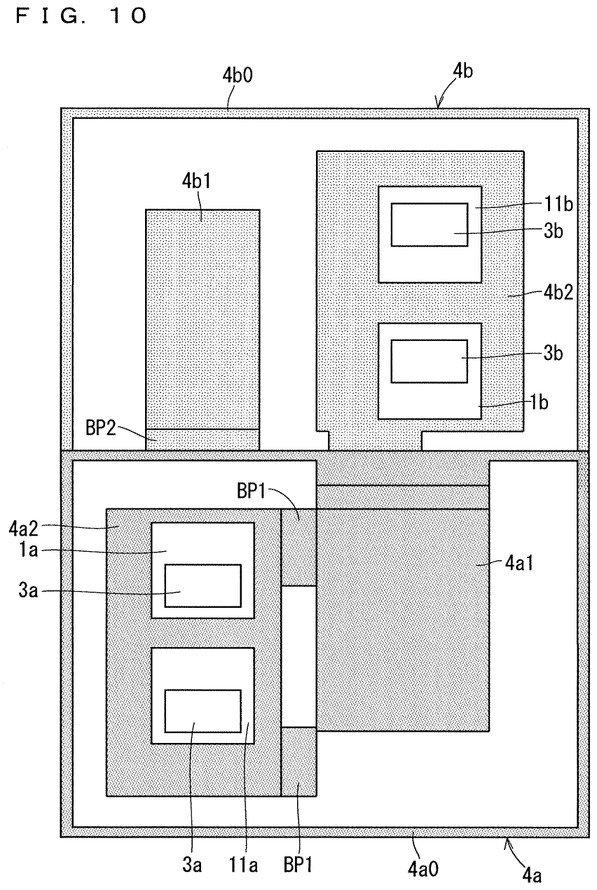

FIG. 9 is a schematic cross-sectional view in a case where the single-phase inverter 200 configured by combining the frame 4a and the frame 4b illustrated in FIG. 8 is resin-sealed and corresponds to a cross-sectional view in an arrow direction taken along a line C-C in FIG. 8.

In FIG. 8, while a cooling fin 6 is attached to the single-phase inverter 200 that is resin-sealed with the molding resin RG, as a result of a slit being formed between the electrode plate 4a1 and the heat spreader 4a2, a through-hole TH penetrating the molding resin RG in a thickness direction can be provided between the electrode plate 4b1 and the electrode plate 4a1 and between the heat spreader 4a2 and the heat spreader 4b2. The single-phase inverter 200 can be attached to the cooling fin 6 by causing the screw 7 to pass through the through-hole TH. As described above, in the single-phase inverter 200, a position through which the screw 7 passes can be secured.

### Third Embodiment

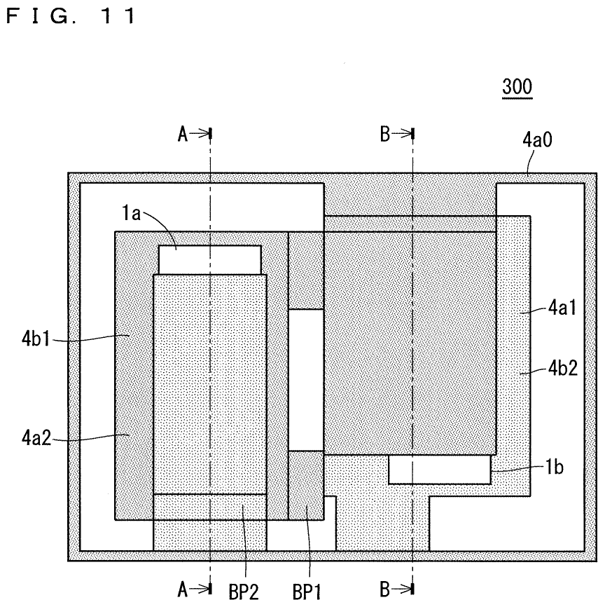

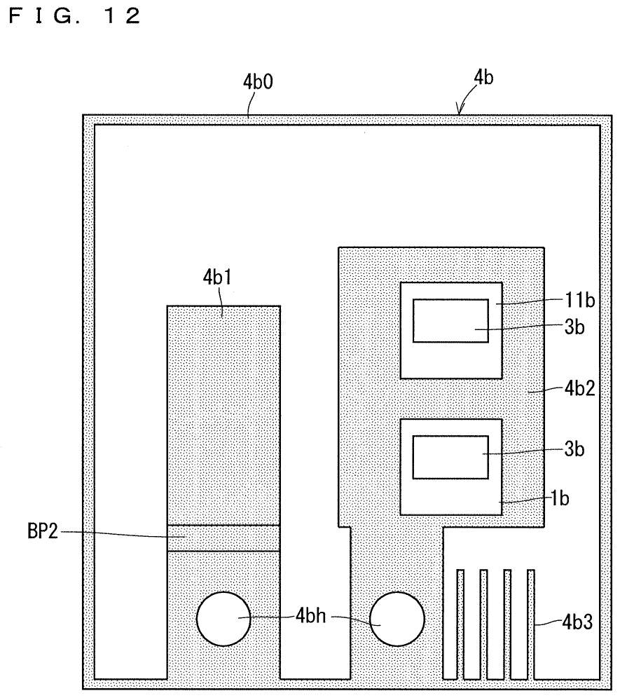

Next, a third embodiment according to the present disclosure will be described with reference to FIGS. 10 and 11. FIG. 10 is a plan view illustrating a state in the middle of superimposing the frame 4b and the frame 4a, and FIG. 11 is a plan view illustrating a state in which the frame 4a and the frame 4b are combined and illustrates a main part of a single-phase inverter 300 of the second embodiment.

In FIG. 10, the frame 4b has the same shape as that of the first embodiment illustrated in FIG. 2, but in the frame 4a, the bent portion BP1 connecting the electrode plate 4a1 and the heat spreader 4a2 is not provided along the entire one long side of the heat spreader 4a2, but is provided so as to connect two portions separated from each other of the one long side and two portions separated from each other of one long side of the electrode plate 4a1. Thus, it can be said that the bent portion BP1 is provided so as to form an opening portion between the electrode plate 4a1 and the heat spreader 4a2.

As illustrated in FIG. 11, the opening portion is formed between the electrode plate 4a1 and the heat spreader 4a2, so that a gap between the heat spreader 4b2 and the heat spreader 4a2 can be used.

As described with reference to FIG. 9 in the second embodiment, the gap is used as a position through which a screw passes when the cooling fin is attached to the single-phase inverter 300. In addition, as compared with a case where a slit is formed between the electrode plate 4a1 and the heat spreader 4a2, engagement between the electrode plate 4a1 and the heat spreader 4a2 becomes stronger, and a shape of the electrode plate 4a1 can be stabilized.

### Fourth Embodiment

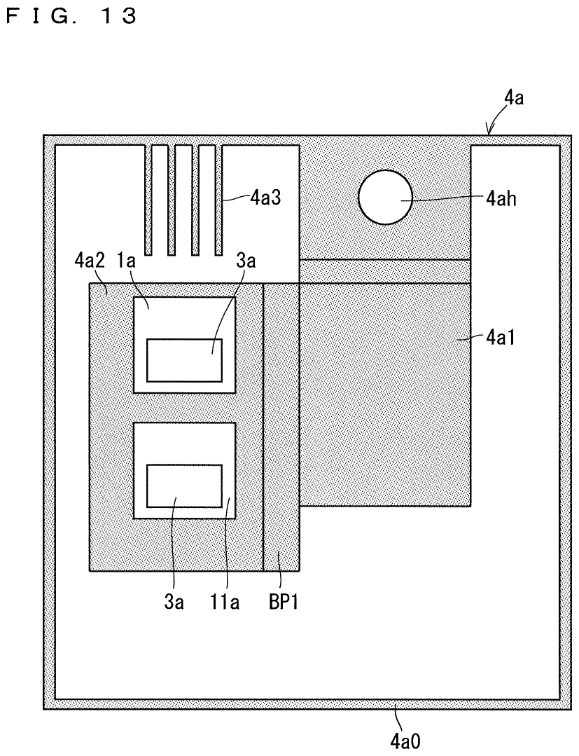

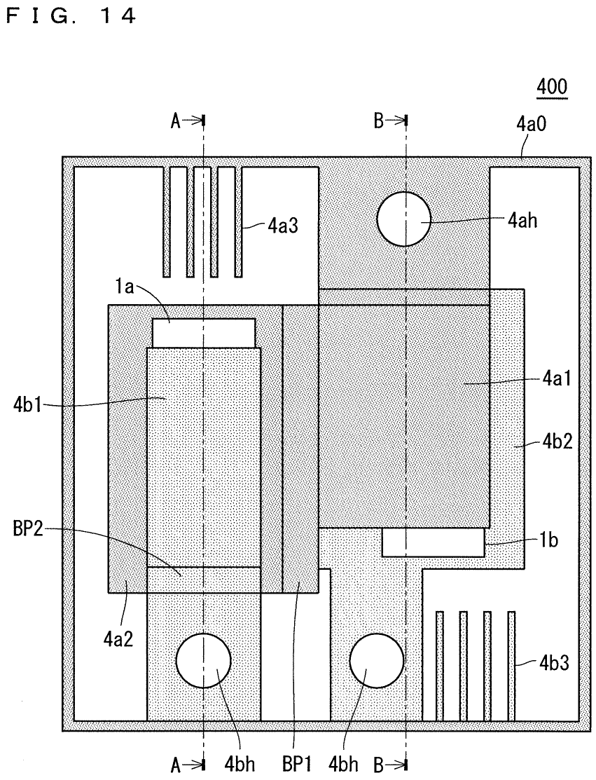

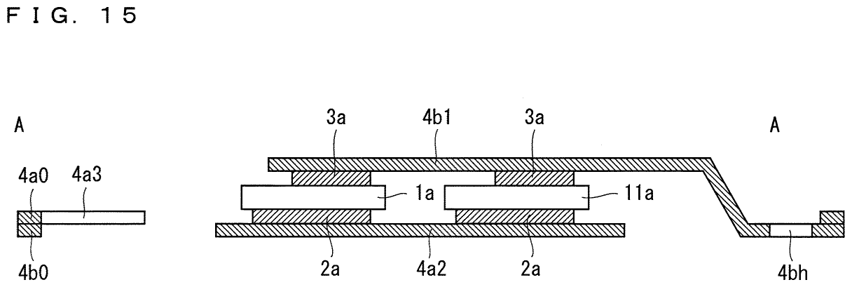

Next, a fourth embodiment according to the present disclosure will be described with reference to FIGS. 12 to 16. FIGS. 12 and 13 are plan views illustrating the frame 4b and the frame 4a for manufacturing a single-phase inverter 400 according to the fourth embodiment, respectively. FIG. 14 is a plan view illustrating a state in which the frame 4a and the frame 4b are combined and illustrates a main part of the single-phase inverter 400 according to the fourth embodiment. In FIGS. 12 to 16, the same components as those in FIGS. 2 to 6 of the first embodiment are denoted by the same reference numerals, and redundant description is omitted.

As illustrated in FIG. 12, the frame 4b includes a frame body 4b0 that defines outline of the frame 4b, the electrode plate 4b1, the heat spreader 4b2, and relay terminals 4b3 (second relay terminals).

The frame body 4b0 is a frame having a rectangular shape in plan view and is provided such that the electrode plate 4b1, the heat spreader 4b2, and the plurality of relay terminals 4b3 extend inward from one side of the frame body 4b0. At one end portion of the electrode plate 4b1, a terminal hole 4bh is provided at a position closer to the frame body 4b0 than the bent portion BP2. In addition, in the heat spreader 4b2, an end portion on a side where the power semiconductor element 1b is mounted has a partially narrowed width and is integrated with the frame body 4b0, and the terminal hole 4bh is provided at a position on the frame body 4b0 side. A portion at which the terminal hole 4bh is provided functions as a main terminal of a so-called single-phase inverter 400, and the terminal hole 4bh functions as a mounting hole for connecting a wiring with the outside. The plurality of relay terminals 4b3 extend to the vicinity of the power semiconductor element 1b on the heat spreader 4b2 in plan view.

As illustrated in FIG. 13, the frame 4a includes a frame body 4a0 that defines outline of the frame 4a, the electrode plate 4a1, the heat spreader 4a2, and a plurality of relay terminals 4a3 (first relay terminals).

The frame body 4a0 is a frame having a rectangular shape in plan view and is provided such that the electrode plate 4a1 and the plurality of relay terminals 4a3 extend inward from one side of the frame body 4a0. At one end portion of the electrode plate 4a1, a terminal hole 4ah is provided at a position on the frame body 4a0 side. The portion at which the terminal hole 4ah is provided functions as a main terminal of a so-called single-phase inverter 400, and the terminal hole 4ah functions as a mounting hole for connecting a wiring with the outside. The plurality of relay terminals 4b3 extend to the vicinity of the power semiconductor element 1a on the heat spreader 4a2 in plan view. The plurality of relay terminals 4a3 function as terminals for wire connection with a control terminal on an upper surface of the power semiconductor element 1a.

As illustrated in FIGS. 12 and 13, one side of the frame body 4b0 in which the electrode plate 4b1, the heat spreader 4b2, and the plurality of relay terminals 4b3 of the frame 4b extend and one side in which the electrode plate 4a1 and the plurality of relay terminals 4a3 of the frame 4a extend have a positional relationship of facing each other, and if the frame 4b and the frame 4a are positioned so as to be superimposed, a configuration as illustrated in FIG. 14 is obtained.

FIG. 14 illustrates a configuration of a region sealed with the molding resin RG of the single-phase inverter 100 illustrated in FIG. 1, in which the power semiconductor elements 1a and 11a are positioned between the heat spreader 4a2 and the electrode plate 4b1, and the power semiconductor elements 1b and 11b are positioned between the heat spreader 4b2 and the electrode plate 4a1.

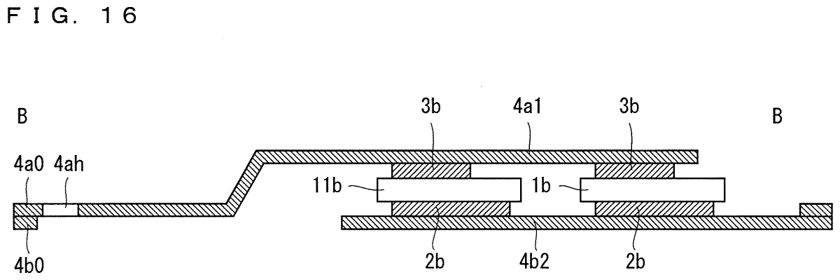

FIG. 15 is a cross-sectional view in an arrow direction taken along a line A-A in FIG. 14, and FIG. 16 is a cross-sectional view in an arrow direction taken along a line B-B.

As illustrated in FIG. 15, the power semiconductor elements 1a and 11a are bonded to the heat spreader 4a2 by the brazing material 2a and are bonded to the upper electrode plate 4b1 by a brazing material 3a.

As illustrated in FIG. 16, the power semiconductor elements 1b and 11b are bonded to the heat spreader 4b2 by a brazing material 2b and are bonded to the upper electrode plate 4a1 by the brazing material 3b.

As described above, the frame 4a is provided with the plurality of relay terminals 4a3 and the portion functioning as the main terminal, and the frame 4b is provided with the plurality of relay terminals 4b3 and the portion functioning as the main terminal, so that the number of components required for assembling the single-phase inverter 400 can be reduced, and productivity can be improved.

In addition, as illustrated in FIG. 12, in the frame 4b, the configuration in which the plurality of relay terminals 4b3 extend to the vicinity of the power semiconductor element 1b on the heat spreader 4b2 in plan view is illustrated, but in this case, by using an IGBT or an MOSFET as the power semiconductor element 1b close to the plurality of relay terminals 4b3 and using the plurality of relay terminals 4b3 as terminals for wire bonding with a control terminal of the IGBT or the MOSFET, the wire bonding is facilitated, and productivity can be improved. Note that the power semiconductor element 11b is a high withstand voltage diode.

Similarly, as illustrated in FIG. 13, the frame 4a has a configuration in which the plurality of relay terminals 4a3 extend to the vicinity of the power semiconductor element 1a on the heat spreader 4a2 in plan view. In this case, by using an IGBT or a MOSFET as the power semiconductor element 1a close to the plurality of relay terminals 4a3 and using the plurality of relay terminals 4a3 as terminals for wire bonding with a control terminal of the IGBT or the MOSFET, the wire bonding is facilitated, and productivity can be improved. Note that the power semiconductor element 11b is a high withstand voltage diode.

### Fifth Embodiment

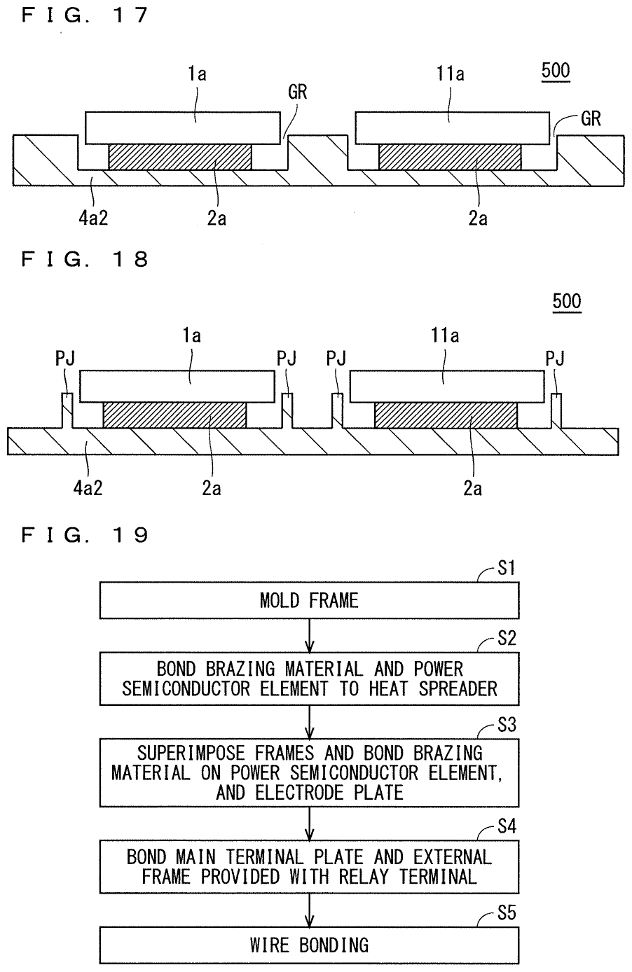

Next, a fifth embodiment according to the present disclosure will be described with reference to FIGS. 17 and 18. FIG. 17 is a cross-sectional view illustrating a cross-sectional configuration of the heat spreader 4a2 constituting a single-phase inverter 500 of the fifth embodiment, and grooves GR (first grooves) for positioning the power semiconductor elements 1a and 11a are provided on a surface of the heat spreader 4a2 on which the semiconductor element is mounted.

The grooves GR are formed to have a depth and a size that prevent the power semiconductor elements 1a and 11a positioned on the brazing material 2a from being displaced from positions on the brazing material 2a. The grooves GR are provided in a direction orthogonal to an arrangement direction of the power semiconductor elements 1a and 11a and has a depth capable of accommodating the brazing material 2a and also accommodating part of the power semiconductor elements 1a and 11a.

By providing the grooves GR, positioning accuracy when the power semiconductor elements 1a and 11a are positioned on the brazing material 2a is improved, and the power semiconductor elements 1a and 11a can be prevented from being displaced from positions on the brazing material 2a.

Note that, although FIG. 17 illustrates an example in which the grooves GR are provided in the heat spreader 4a2, grooves GR (second grooves) can also be provided in the heat spreader 4b2 to improve positioning accuracy of the power semiconductor elements 1b and 11b and prevent displacement of the power semiconductor elements 1b and 11b.

FIG. 18 is a cross-sectional view illustrating a configuration in which projections PJ are provided instead of the grooves GR on the surface of the heat spreader 4a2 on which the semiconductor element is mounted. As illustrated in FIG. 18, the projections PJ are formed at a height that prevents the power semiconductor elements 1a and 11a positioned on the brazing material 2a from being displaced from positions on the brazing material 2a. The projections PJ are provided on an outer side in plan view in each of the power semiconductor elements 1a and 11a, and has a height exceeding a thickness of the brazing material 2a and reaching part of the thickness of the power semiconductor elements 1a and 11a. Note that, in FIG. 18, the projections PJ are provided in front of and behind each of the power semiconductor elements 1a and 11a, but can also be provided on the left and right of each of the power semiconductor elements 1a and 11a, and can also be provided in front of and behind, and on the left and right.

By providing the projections PJ, the positioning accuracy when the power semiconductor elements 1a and 11a are positioned on the brazing material 2a is improved, and the power semiconductor elements 1a and 11a can be prevented from being displaced from positions on the brazing material 2a.

Note that, although FIG. 18 illustrates an example in which the projections PJ are provided in the heat spreader 4a2, the projections PJ can also be provided in the heat spreader 4b2 to improve positioning accuracy of the power semiconductor elements 1b and 11b and prevent displacement of the power semiconductor elements 1b and 11b.

### Sixth Embodiment

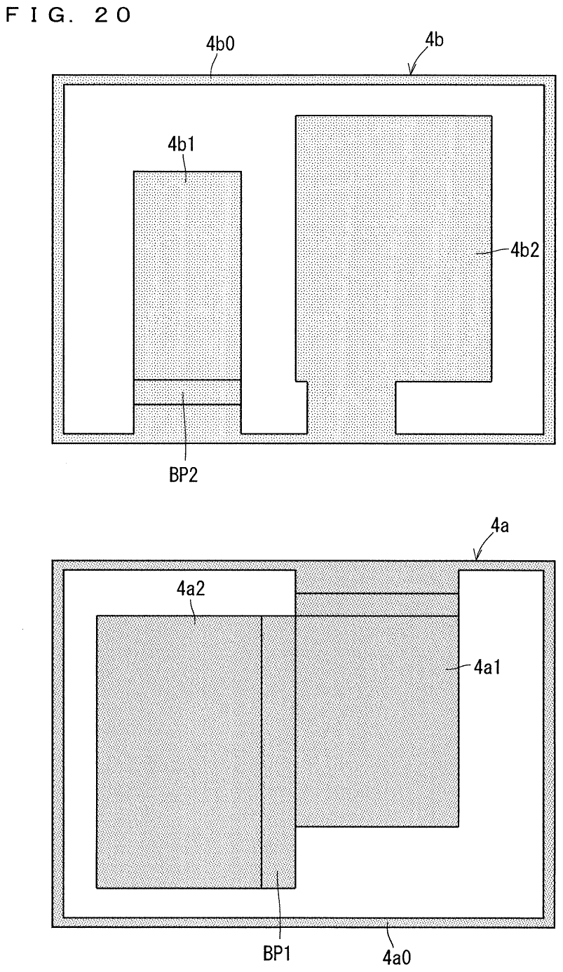

Next, as a sixth embodiment according to the present disclosure, a method of manufacturing the single-phase inverter 100 illustrated in FIG. 1 will be described with reference to FIGS. 20 to 24 while referring to the flowchart indicated in FIG. 19.

In step S1 indicated in FIG. 19, a frame is molded. As illustrated in FIG. 20, this is a step of preparing the frames 4a and 4b, and the frames 4a and 4b are formed by punching and bending. The frames 4a and 4b illustrated in FIG. 20 are states before the power semiconductor elements are mounted on the frame 4a illustrated in FIG. 3 and the frame 4b illustrated in FIG. 2, respectively.

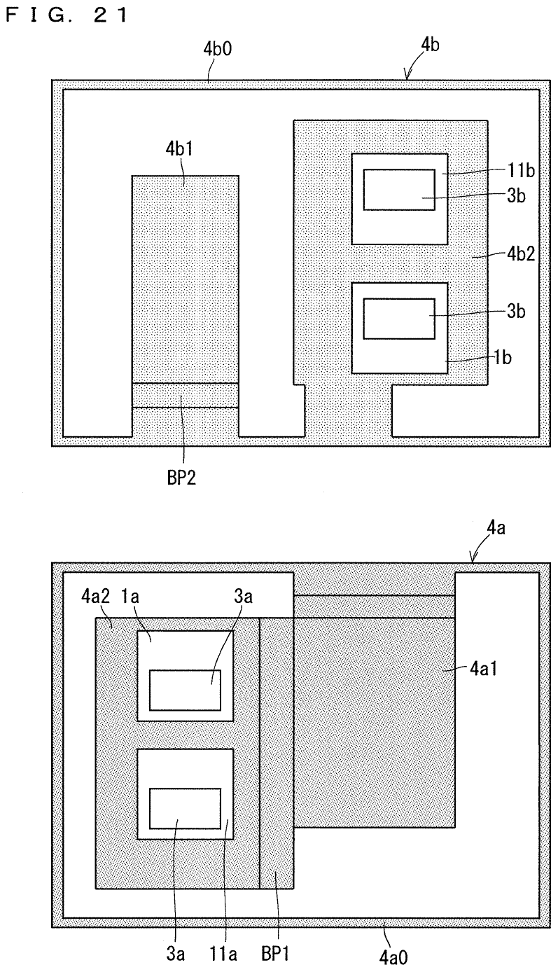

Next, in step S2, the power semiconductor element is bonded to the heat spreader with a brazing material. As illustrated in FIG. 21, this is a step of bonding the power semiconductor elements 1a and 11a to the heat spreader 4a2 of the frame 4a via the brazing material 2a (not illustrated) and bonding the power semiconductor elements 1b and 11b to the heat spreader 4b2 of the frame 4b via the brazing material 2b (not illustrated), and is a step of melting the brazing material. The frames 4a and 4b illustrated in 21 are the states of the frame 4a illustrated in FIG. 3 and the frame 4b illustrated in FIG. 2, respectively. The brazing material 3a is positioned on the power semiconductor elements 1a and 11a for the next step, and the brazing material 3b is positioned on the power semiconductor elements 1b and 11b for the next step.

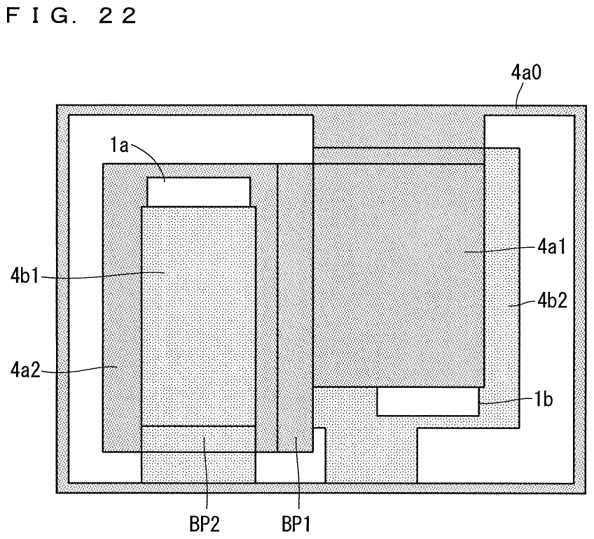

Next, in step S3, the two frames are superimposed, and the electrode plate is bonded with the brazing material on the power semiconductor element. As illustrated in FIG. 22, this is a step of superimposing the frame 4a and the frame 4b, bonding the brazing material 3a (not illustrated) on the power semiconductor elements 1a and 11a of the frame 4a and the electrode plate 4b1 of the frame 4b, and bonding the brazing material 3b (not illustrated) on the power semiconductor elements 1b and 11b of the frame 4b and the electrode plate 4a1 of the frame 4a, and is a step of melting the brazing material. Note that the state in which the frame 4a and the frame 4b illustrated in FIG. 22 are superimposed corresponds to the state illustrated in FIG. 4.

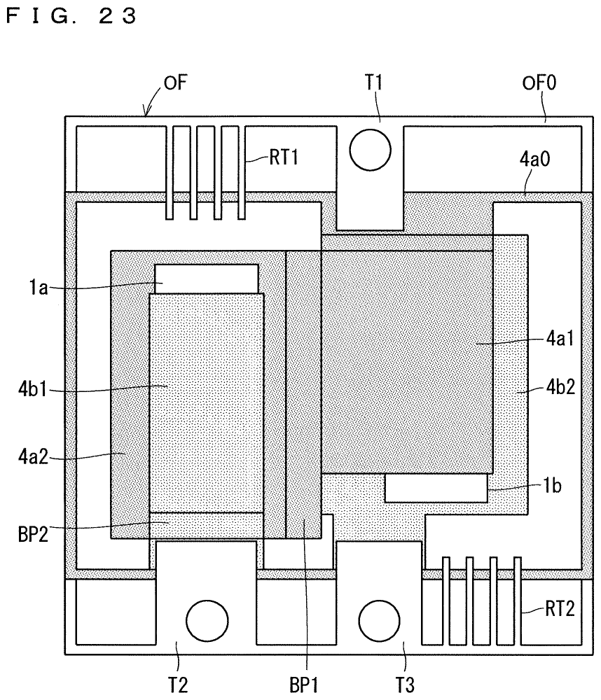

Next, in step S4, the main terminal plate and an external frame provided with the relay terminals are bonded. This is a step of bonding an external frame OF to the frames 4a and 4b in a state where the bonding between the power semiconductor element and the electrode plate is completed, as illustrated in FIG. 23.

The external frame OF is bonded so as to be further superimposed on the superimposed frames 4a and 4b, and includes a frame body OF0 defining outline of the external frame OF, main terminal plates T1, T2, and T3, and relay terminals RT1 and RT2.

The frame body OF0 is a frame having a rectangular shape in plan view and is provided such that the main terminal plate T1 and the relay terminal RT1 extend inward from one side of the frame body OF0. The main terminal plate T1 is provided at a position to be bonded to the end portion of the electrode plate 4a1, and the relay terminal RT1 is provided at a position facing the power semiconductor element 1a.

Further, the main terminal plates T2 and T3 and the relay terminal RT2 are provided so as to extend inward from one side of the frame body OF0 opposite to the one side on which the main terminal plate T1 and the relay terminal RT1 extend. The main terminal plate T2 is provided at a position to be bonded to the end portion of the electrode plate 4b1, the main terminal plate T3 is provided at a position to be bonded to the end portion of the heat spreader 4b2, and the relay terminal RT2 is provided at a position facing the power semiconductor element 1b.

Note that ultrasonic (US) bonding can be used for bonding the external frame OF and the frames 4a and 4b. Further, bonding via a brazing material can also be used.

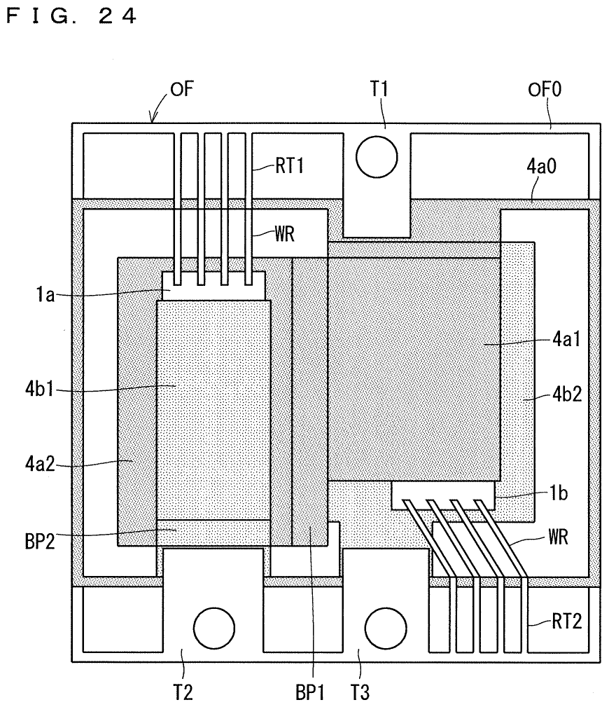

Next, in step S5, the relay terminal and the power semiconductor element are connected by wire bonding. As illustrated in FIG. 24, this is a step of connecting the relay terminal RT1 and the control terminal of the power semiconductor element 1a by the wire WR, and connecting the relay terminal RT2 and the control terminal of the power semiconductor element 1b by the wire WR.

Thereafter, unnecessary portions of the frame body OFO and the frame bodies 4a0 and 4b0 are cut, and a main part of the single-phase inverter 100 is sealed with the molding resin RG, so that the single-phase inverter 100 illustrated in FIG. 1 is obtained.

### Seventh Embodiment

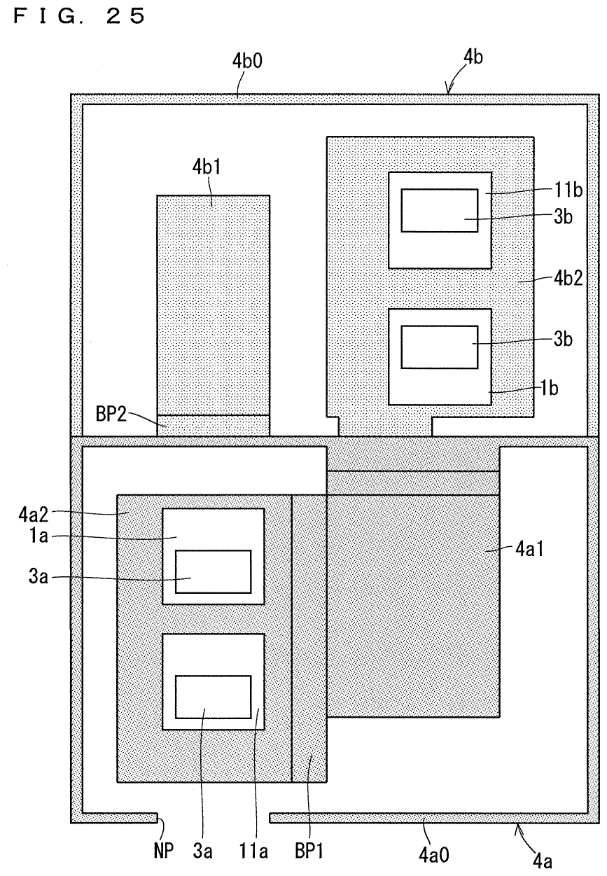

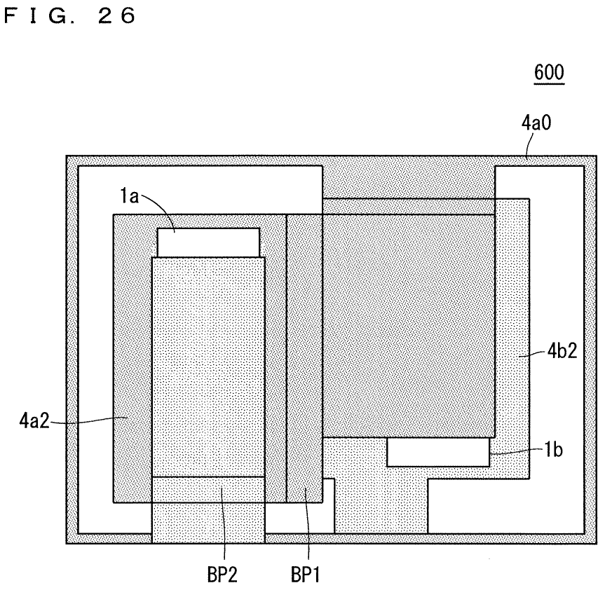

Next, a seventh embodiment according to the present disclosure will be described with reference to FIGS. 25 and 26. FIG. 25 is a plan view illustrating a state in the middle of superimposing the frame 4b and the frame 4a, and FIG. 26 is a plan view illustrating a state in which the frame 4a and the frame 4b are combined and illustrates a main part of a single-phase inverter 600 of the seventh embodiment.

In FIG. 25, the frame 4b has the same shape as that of the first embodiment illustrated in FIG. 2, but the frame 4a has a notch portion NP in which part of the frame body 4a0 is cut out. The notch portion NP is provided at a position where an end portion of the electrode plate 4b1 of the frame 4b is engaged with the frame body 4a0 in a case where the frame 4a and the frame 4b are combined. Thus, when the frame 4a and the frame 4b are superimposed and bonded, the frame body 4a0 and the end portion of the electrode plate 4b1 do not overlap each other, which facilitates the bonding.

### Eighth Embodiment

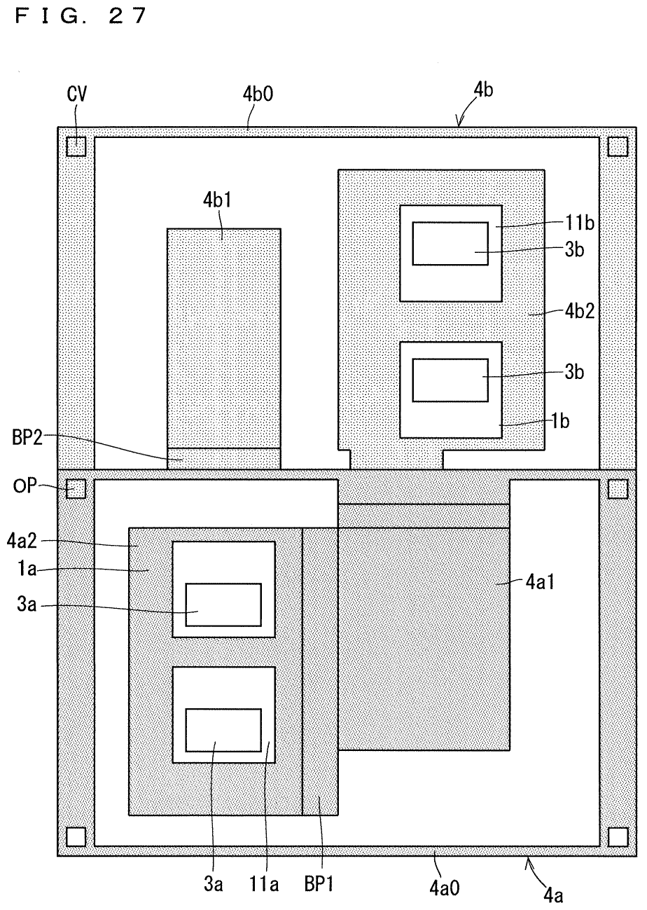

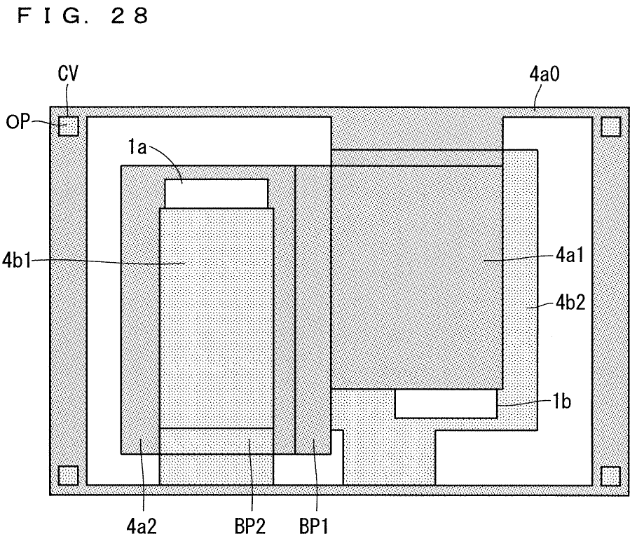

Next, an eighth embodiment according to the present disclosure will be described with reference to FIGS. 27 and 28. FIG. 27 is a plan view illustrating a state in the middle of superimposing the frame 4b and the frame 4a, and FIG. 28 is a plan view illustrating a state in which the frame 4a and the frame 4b are combined.

As illustrated in FIG. 27, the frame body 4b0 of the frame 4b has protrusions CV on two sides in a left-right direction parallel to the arrangement of the electrode plate 4b1 and the heat spreader 4b2. The protrusions CV are provided at four corner portions of the frame body 4b0 and protrude to the side on which the frame 4a is superimposed.

On the other hand, as illustrated in FIG. 27, the frame body 4a0 of the frame 4a has opening portions OP on two sides in the left-right direction parallel to the arrangement of the electrode plate 4a1 and the heat spreader 4a2. The opening portions OP are provided at four corner portions of the frame body 4a0, and as illustrated in FIG. 28, the opening portions OP are provided at positions where the protrusions CV are inserted into the opening portions OP when the frame 4a is superimposed on the frame 4b. Thus, positioning accuracy when the frame 4a and the frame 4b are superimposed is improved.

### Ninth Embodiment

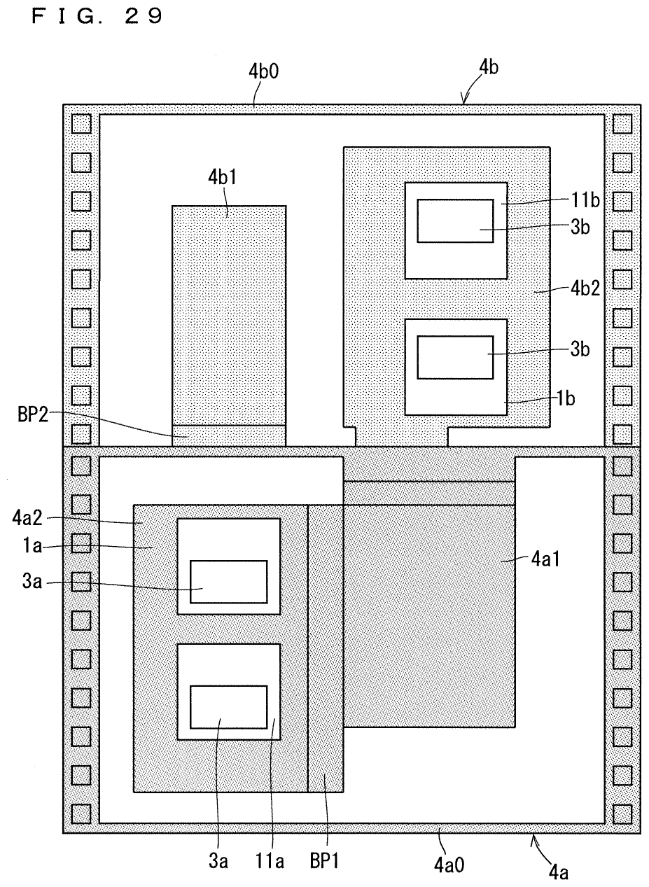

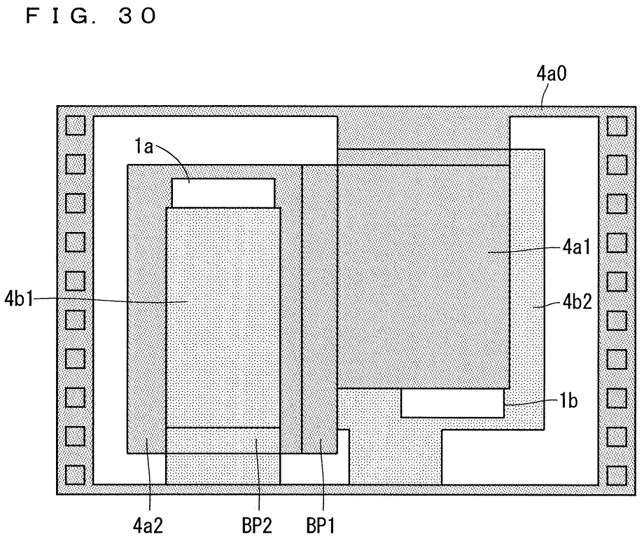

Next, a ninth embodiment according to the present disclosure will be described with reference to FIGS. 29 and 30. FIG. 29 is a plan view illustrating a state in the middle of superimposing the frame 4b and the frame 4a, and FIG. 30 is a plan view illustrating a state in which the frame 4a and the frame 4b are combined.

As illustrated in FIG. 29, the frame body 4b0 of the frame 4b has a plurality of dimples DP2 (second dimples) on two sides in the left-right direction parallel to the arrangement of the electrode plate 4b1 and the heat spreader 4b2. The plurality of dimples DP2 are provided in one row along the extending direction of each side on two sides in the left-right direction.

Similarly, the frame body 4a0 of the frame 4a also has a plurality of dimples DP1 (first dimples) on two sides in the left-right direction parallel to the arrangement of the electrode plate 4a1 and the heat spreader 4a2. The plurality of dimples DP1 are provided in one row along the extending direction of each side on two sides in the left-right direction.

The plurality of dimples DP1 and DP2 of the frames 4a and 4b are provided so as to be recessed in the same direction at positions overlapping with each other as illustrated in FIG. 30 when the frame 4a is superimposed on the frame 4b. Thus, positioning accuracy when the frame 4a and the frame 4b are superimposed is improved.

### Tenth Embodiment

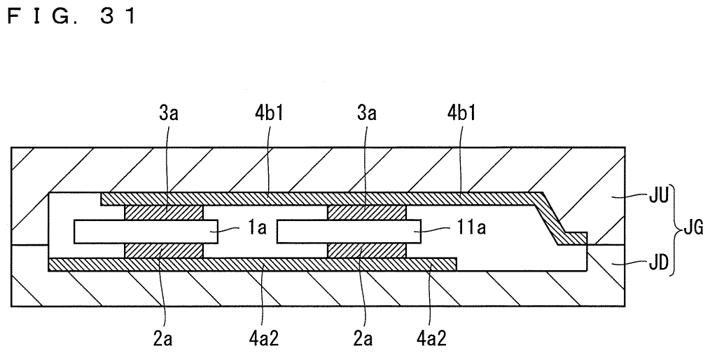

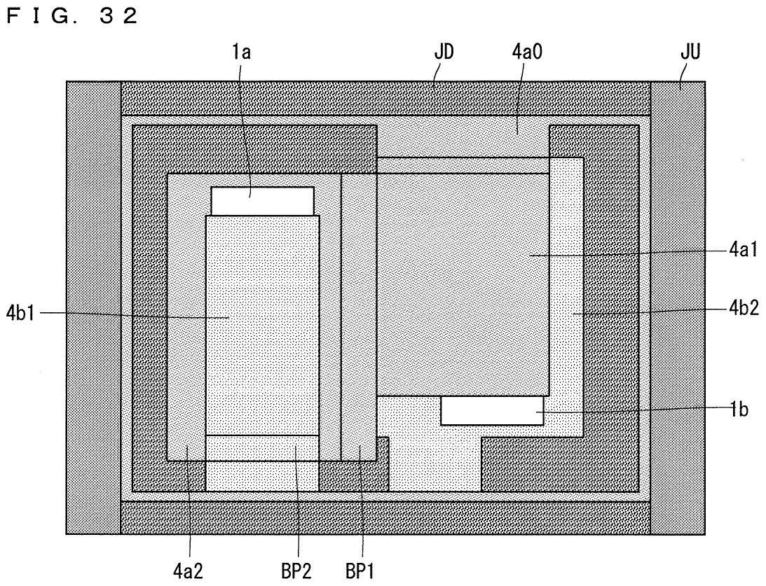

Next, a tenth embodiment according to the present disclosure will be described with reference to FIGS. 31 and 32. FIG. 31 is a cross-sectional view for explaining a state in which the frame 4a and the frame 4b are superimposed and the electrode plate is bonded by the brazing material on the power semiconductor element, and is a cross-sectional view corresponding to FIG. 5 described in the first embodiment, and is a view for explaining the contrivance in step S3 of the flowchart indicated in FIG. 19 in the sixth embodiment.

As illustrated in FIG. 31, a step of melting the brazing material is performed in a state where the superimposed frames 4a and 4b are fixed by a fixing jig JG. The fixing jig JG includes a lower fixing jig JD positioned below the superimposed frames 4a and 4b, that is, on the heat spreader 4a2 side, and an upper fixing jig JU positioned above the superimposed frames 4a and 4b, that is, on the electrode plate 4b1 side.

As illustrated in FIG. 31, by sandwiching the superimposed frames 4a and 4b between the lower fixing jig JD and the upper fixing jig JU, the frames 4a and 4b are prevented from being displaced when the brazing material is melted, and the positioning accuracy of the electrode plate is improved.

In FIG. 31, the configuration in which the entire superimposed frames 4a and 4b are sandwiched by the fixing jig JG is illustrated, but the present disclosure is not limited thereto, and a configuration in which only part of the frames is sandwiched may be adopted.

FIG. 32 is a plan view illustrating the fixing jig JG sandwiching only part of the frames. FIG. 32 illustrates a configuration in which the left and right frame bodies of the superimposed frames 4a and 4b are sandwiched between the lower fixing jig JD and the upper fixing jig JU. The upper fixing jig JU is positioned only on the left and right frame bodies of the superimposed frames 4a and 4b. In a case where such a fixing jig JG is used, it is also possible to make the process proceed to the next wire bonding process while sandwiching the superimposed frames 4a and 4b by the fixing jig JG.

Examples of a material of the fixing jig JG include carbon that can withstand a temperature at the time of melting the brazing material and has little deformation.

### Semiconductor Material of Power Semiconductor Element

The power semiconductor elements 1a, 1b, 11a, and 11b are not limited to silicon semiconductor elements using silicon (Si), and wide bandgap semiconductor elements such as silicon carbide semiconductor elements using silicon carbide (SiC) and gallium nitride semiconductor elements using gallium nitride (GaN) can be used. Compared with a silicon semiconductor element, a wide bandgap semiconductor element can be downsized, has excellent withstand voltage, has high allowable current density, and has high heat resistance, and thus can operate at a high temperature, and is expected to have high efficiency.

### Modifications

In the first to the tenth embodiments described above, the configuration in which the present disclosure is applied to the single-phase inverter has been described, but the present disclosure is not limited thereto, and the present disclosure can also be applied to a three-phase inverter in which single-phase inverters corresponding to three phases are combined, and can also be applied to a converter for power regeneration.

Note that in the present disclosure, the embodiments can be freely combined or can be appropriately modified or omitted within a scope of the disclosure.

Although the present disclosure has been described in detail, the above description is illustrative in all aspects, and the present disclosure is not limited thereto. It is understood that numerous modifications not exemplified can be assumed without departing from the scope of the present disclosure.

1. A semiconductor device comprising:
a first heat spreader on which a first semiconductor element is mounted;
a first electrode plate connected to the first heat spreader at a bent portion having an inclination;
a second heat spreader on which a second semiconductor element is mounted; and
a second electrode plate provided to have a level difference with respect to the second heat spreader,
wherein the first electrode plate is positioned at a position higher than the first heat spreader,
the second electrode plate is positioned at a position higher than the second heat spreader,
the first electrode plate and the second electrode plate are positioned at a same height,
the first heat spreader and the second heat spreader are positioned at a same height,
the second electrode plate is positioned above the first heat spreader,
the first electrode plate is positioned above the second heat spreader,
the first semiconductor element is bonded to the first heat spreader and the second electrode plate, and
the second semiconductor element is bonded to the second heat spreader and the first electrode plate.

2. The semiconductor device according to claim 1, wherein the first heat spreader and the first electrode plate have a parallel positional relationship in plan view, and the bent portion is provided along an entire side of the first heat spreader facing the first electrode plate.

3. The semiconductor device according to claim 1, wherein the first heat spreader and the first electrode plate have a parallel positional relationship in plan view, the bent portion is provided in part of one side of the first heat spreader facing the first electrode plate, and a slit is formed between the first heat spreader and the first electrode plate.

4. The semiconductor device according to claim 1, wherein the first heat spreader and the first electrode plate have a parallel positional relationship in plan view, the bent portion is provided in a first portion and a second portion separated from each other on one side of the first heat spreader facing the first electrode plate, and an opening portion is formed between the first heat spreader and the first electrode plate.

5. The semiconductor device according to claim 1, wherein
the first heat spreader and the first electrode plate have a parallel positional relationship in plan view, the semiconductor device further comprises a plurality of first relay terminals provided in parallel to the first heat spreader in plan view,
the first semiconductor element is positioned at a position closer to the plurality of first relay terminals on the first heat spreader,
the second heat spreader and the second electrode plate have a parallel positional relationship in plan view, the semiconductor device further comprises a plurality of second relay terminals provided in parallel to the second heat spreader in plan view, and
the second semiconductor element is positioned at a position closer to the plurality of second relay terminals on the second heat spreader.

6. The semiconductor device according to claim 5, wherein the first semiconductor element and the second semiconductor element are IGBTs or MOSFETs.

7. The semiconductor device according to claim 1, wherein
the first heat spreader includes a first groove in a portion on which the first semiconductor element is mounted, the first groove matching a size of the first semiconductor element in plan view, and
the second heat spreader includes a second groove in a portion on which the second semiconductor element is mounted, the second groove matching a size of the second semiconductor element in plan view.

8. The semiconductor device according to claim 1, wherein
the first heat spreader includes a plurality of first projections provided at positions outside the first semiconductor element in plan view in a portion on which the first semiconductor element is mounted, and
the second heat spreader includes a plurality of second projections provided at positions outside the second semiconductor element in plan view in a portion on which the second semiconductor element is mounted.

9. The semiconductor device according to claim 1, wherein the first semiconductor element is a silicon carbide semiconductor element.

10. A method of manufacturing a semiconductor device using:
a first heat spreader to which a first semiconductor element is bonded;
a first frame including a first electrode plate connected to the first heat spreader at a bent portion having an inclination; and
a second frame including a second heat spreader to which a second semiconductor element is bonded and a second electrode plate provided to have a level difference with respect to the second heat spreader,
wherein the first electrode plate is positioned at a position higher than the first heat spreader,
the second electrode plate is positioned at a position higher than the second heat spreader, and
the first electrode plate and the second electrode plate are positioned at a same height,
the first heat spreader and the second heat spreader are positioned at a same height,
the second electrode plate is positioned above the first heat spreader,
the first electrode plate is positioned above the second heat spreader,
the method comprising:
a step (a) of superimposing the first frame and the second frame so that the first semiconductor element is sandwiched between the first heat spreader and the second electrode plate, and the second semiconductor element is sandwiched between the second heat spreader and the first electrode plate; and
a step (b) of melting a first brazing material positioned between the first semiconductor element and the second electrode plate and a second brazing material positioned between the second semiconductor element and the first electrode plate to bond the first semiconductor element to the second electrode plate and bond the second semiconductor element to the first electrode plate.

11. The method of manufacturing the semiconductor device according to claim 10, wherein the first frame includes a notch portion at a portion that comes into contact with the second electrode plate in a case where the first frame and the second frame are superimposed.

12. The method of manufacturing the semiconductor device according to claim 10, wherein
the second frame includes a plurality of protrusions,
the first frame includes a plurality of opening portions provided at positions corresponding to the plurality of protrusions of the second frame, and
in the step (a), the first frame and the second frame are superimposed so that the plurality of protrusions are inserted into the plurality of opening portions.

13. The method of manufacturing the semiconductor device according to claim 10, wherein
the second frame includes a plurality of second dimples, and
the first frame includes a plurality of first dimples provided at positions corresponding to the plurality of second dimples of the second frame, and
in the step (a), the first frame and the second frame are superimposed so that the plurality of first dimples and the plurality of second dimples overlap each other.

14. The method of manufacturing the semiconductor device according to claim 10, wherein the step (b) includes a step of pressing upper and lower portions of the superimposed first frame and second frames using a fixing jig.

15. The method of manufacturing the semiconductor device according to claim 10, wherein the first frame and the second frame are configured to have a same outer size.
